(19) United States
(12) Patent Application Publication
(10) Pub. No.: US 2025/0056882 A1
(43) Pub. Date: Feb. 13, 2025

(54) DISPLAY PANEL, MANUFACTURING METHOD THEREOF, AND DISPLAY DEVICE

(71) Applicant: Shenzhen China Star Optoelectronics Semiconductor Display Technology Co., Ltd., Shenzhen (CN)

(72) Inventor: Chuanbao LUO, Shenzhen (CN)

(73) Assignee: Shenzhen China Star Optoelectronics Semiconductor Display Technology Co., Ltd., Shenzhen (CN)

(21) Appl. No.: 18/526,200

(22) Filed: Dec. 1, 2023

(30) Foreign Application Priority Data
Aug. 7, 2023 (CN) 202310987453.7

(51) Int. Cl. H01L 27/12

(52) U.S. Cl. CPC H01L 27/1251; H01L 27/1288; H01L 27/1225

(57) ABSTRACT

A display panel, a manufacturing method of the display panel, and a display device are provided. The display panel includes a display area and a non-display area. The non-display area surrounds the display area. The display panel further includes: a substrate; a first thin film transistor (TFT) disposed in the non-display area, where the first TFT includes a first drain layer placed on one side of the substrate; a second TFT arranged in the display area, where the second TFT includes a second gate layer placed on one side of the substrate. The first drain layer and the second gate layer are arranged in a same layer. By forming the second gate layer and the first drain layer in a same process, the number of photomask processes can be reduced compared to the conventional display panel. This reduces the number of steps.

### CROSS-REFERENCE TO RELATED APPLICATION

This application claims the benefit of priority of Chinese Patent Application No. 202310987453.7, filed on Aug. 7, 2023, the disclosure of which is incorporated herein by reference in its entirety.

### FIELD OF DISCLOSURE

The present application relates to a field of display technology and in particular, to a display panel, a manufacturing method thereof, and a display device.

### DESCRIPTION OF RELATED ART

Display panel gate drive technology (Gate Driver on Array, GOA) and column scan drive technology (Demux) are mainstream display technologies for display panels, which offer significant advantages in high-quality display devices, such as low cost and reduced border size. It's widely known that, the GOA and Demux areas need to be driven by large currents. Therefore, in conventional device structures, the size of thin film transistors (TFTs) must be increased to handle the larger current. The size of the TFTs limits the size of the GOA circuit and the size of the border to a certain extent. Additionally, conventional devices have complex and numerous processes.

### SUMMARY OF INVENTION

The present application provides a display panel, a manufacturing method thereof, and a display device, which can save on the photomask processes, thereby reducing the number of steps involved.

The present application provides a display panel, including:
a display area and a non-display area, the non-display area surrounding the display area;
a substrate;
a first thin film transistor (TFT) disposed in the non-display area and comprising a first drain layer, the first drain layer disposed on one side of the substrate; and
a second thin film transistor (TFT) disposed in the display area and comprising a second gate layer, the second gate layer disposed on one side of the substrate;
wherein the first drain layer and the second gate layer are arranged in a same layer.

In some embodiments, the first TFT further includes a first source layer, the first source layer is disposed between the first drain layer and the substrate;
the second TFT further includes a light-shielding layer, the light-shielding layer is disposed between the second gate layer and the substrate; and
the first source layer and the light-shielding layer are arranged in a same layer.

In some embodiments, the first TFT further includes a first interlayer insulating layer, the first interlayer insulating layer is disposed between the first source layer and the first drain layer;
the second TFT further includes a second gate insulating layer, the second gate insulating layer is disposed between the second gate layer and the light-shielding layer; and
the first interlayer insulating layer and the second gate insulating layer are arranged in a same layer.

In some embodiments, the first TFT further includes a first gate layer, the first gate layer is disposed on one side of the first drain layer away from the substrate;
the second TFT further includes a second source layer and a second drain layer; and
the second source layer and the second drain layer are arranged in a same layer as the first gate layer.

In some embodiments, the first TFT further includes a first active layer, and the first active layer covers the first drain layer;
the first active layer includes a first channel region and a first non-channel region connected to each other; and
an extension direction of the first channel region and an extension direction of the first non-channel region forms an angle θ1, which satisfies: 95°≤θ1≤115°.

In some embodiments, the first active layer further includes a second non-channel region, one end of the first channel region is connected to the first non-channel region, and another end of the first channel region is connected to the second non-channel region;
the first gate layer includes a first section, a second section, and a third section connected in sequence;
the second section is arranged corresponding to the first channel region, and a distance L is present between the first channel region and the second section, which satisfies: 50 nm≤L≤200 nm.

Accordingly, the present application further provides a manufacturing method of a display panel, including following steps:
providing a substrate; and
forming a first thin film transistor (TFT) and a second thin film transistor (TFT) on one side of the substrate, wherein the first TFT is disposed in the non-display area, and the second TFT is disposed in the display area;
wherein the first TFT includes a first drain layer, and the first drain layer is disposed on one side of the substrate;
the second TFT includes a second gate layer, the second gate layer is disposed on one side of the substrate;
the first drain layer and the second gate layer are arranged in a same layer.

In some embodiments, the step of forming the first TFT and the second TFT on one side of the substrate includes:
forming a first metal layer on one side of the substrate;
patterning the first metal layer to form a first source layer and a light-shielding layer.

In some embodiments, after patterning the first metal layer to form the first source layer and the light-shielding layer, the manufacturing method further includes:
forming a buffer layer covering the substrate, the first source layer, and the light-shielding layer;
patterning the buffer layer to form a first via hole exposing the first source layer;
forming a first dielectric layer on one side of the buffer layer away from the substrate; and
patterning the first dielectric layer to form a first interlayer insulating layer and a second gate insulating layer.

In some embodiments, after patterning the first dielectric layer to form the first interlayer insulating layer and the second gate insulating layer, the manufacturing method further includes:
forming a second metal layer covering the substrate, the first interlayer insulating layer, and the second gate insulating layer; and
patterning the second metal layer to form a first drain layer and a second gate layer.

In some embodiments, after patterning the second metal layer to form the first drain layer and the second gate layer, the manufacturing method further includes:
forming a first active layer covering the first drain layer and the first via hole, wherein the first active layer includes a first channel region and a first non-channel region connected to each other; and an extension direction of the first channel region and an extension direction of the first non-channel region forms an angle θ1, which satisfies: 95°≤θ1≤115°.

In some embodiments, after forming the first active layer covering the first drain layer and the first via hole, the manufacturing method further includes:
forming a first gate insulating layer covering the first active layer and the second gate layer;
patterning the first gate insulating layer to form a receiving groove, a second via hole, a third via hole, and a fourth via hole;
forming a third metal layer on the first gate insulating layer and in the receiving groove, the second via hole, the third via hole, and the fourth via hole; and
patterning the third metal layer to form a first gate layer in the receiving groove, forming a second source layer in the second via hole and the fourth via hole, and forming a second drain layer in the third via hole.

Correspondingly, the present application further provides a display device, including the display panel mentioned above or including a display panel produced by the manufacturing method mentioned above.

The present application provides a display device. The light-shielding layer and the first source layer are formed in the same process; the second gate insulating layer and the first interlayer insulating layer are formed in the same process; the second gate layer and the first drain layer are formed in the same process; and the second source layer, the second drain layer, and the first gate layer are formed in the same process. Compared with conventional display panels, the photomask processes can be saved and the number of steps can be reduced. In addition, since the first thin film transistor located in the non-display area has a vertical channel structure, the carrier mobility of the first thin film transistor is improved, thereby reducing the size of the display panel and achieving a narrow frame configuration of the display device.

### BRIEF DESCRIPTION OF DRAWINGS

In order to explain the technical solutions in the present application more clearly, the drawings needed to be used in the description of the embodiments will be briefly introduced below. Obviously, the drawings in the following description are only some embodiments of the present application. For those skilled in the art, other drawings can also be obtained based on these drawings without creative efforts.

FIG. 1 is a schematic structural view of a display panel provided by the present application.

FIG. 2 is a process flow diagram of a manufacturing method of the display panel provided by the present application.

FIG. 3 is a process flow diagram illustrating manufacturing a first thin film transistor and a second thin film transistor in the manufacturing method of the display panel provided by the present application.

FIG. 4 is a schematic view of a first step of a manufacturing method process of the display panel provided by the present application.

FIG. 5 is a schematic view of a second step of the manufacturing method of the display panel provided by the present application.

FIG. 6 is a schematic view of a third step of the manufacturing method of the display panel provided by the present application.

FIG. 7 is a schematic view of a fourth step of the manufacturing method of the display panel provided by the present application.

FIG. 8 is a schematic view of a fifth step of the manufacturing method of the display panel provided by the present application.

FIG. 9 is a schematic view of a sixth step of the manufacturing method of the display panel provided by the present application.

FIG. 10 is a schematic view of a seventh step of the manufacturing method of the display panel provided by the present application.

FIG. 11 is a schematic view of an eighth step of the manufacturing method of the display panel provided by the present application.

### DETAILED DESCRIPTION OF EMBODIMENTS

The technical solution of the present application is described more clearly and completely with reference to the accompanying drawings and in conjunction with specific embodiments. It is clear that the described embodiments are just some of the application's embodiments and not all of them. Based on these examples, other embodiments obtained by those skilled in the art without creative efforts are within the protection scope of this application.

It is noted that the “first”, “second”, “third”, “fourth”, etc., mentioned in this application do not indicate any sequence, quantity, or importance, but are used to differentiate various parts. The directional terms “up”, “down”, “left”, “right”, etc., are relative to the directions in the accompanying drawings. Therefore, the use of these numerical, directional, and positional terms is for explaining and understanding this application and not for limiting it. In the drawings, structurally similar units are represented with the same reference numbers/labels.

Technologies like active-driving organic light emitting diode (OLED), micro light emitting diode (Micro LED), mini light emitting diode (Mini LED), etc., which are self-luminous displays, generally require more than two thin-film transistors (TFTs) to control the display state of a single pixel, such as the commonly seen 2T1C circuit or 3T1C circuit. On the other hand, with the rapid development of 5G and IoT, the application scenarios for mobile terminals have become more diversified. Integration of certain circuits reduces costs or enhances product performance. Among the most common are GOA and Demux, which integrate gate driving circuits on the display panel's array substrate, enabling row-by-row scanning and thereby saving parts of the gate driving circuits. Demux refers to the circuit used for data signal selection before the pixel source-drain electrode in the display area, usually adopting a data selection circuit (Demux) for inputting data signals, thus connecting data signals to IC channels.

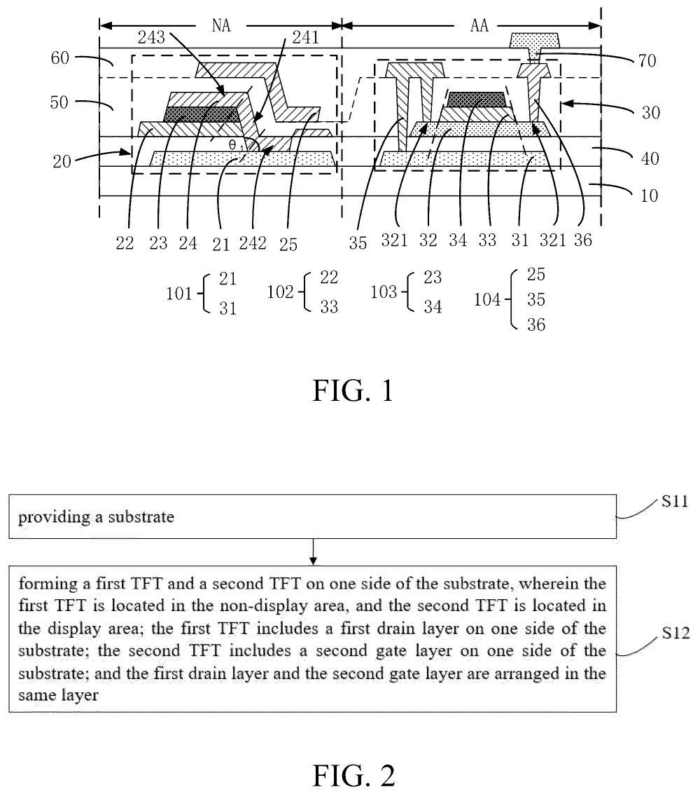

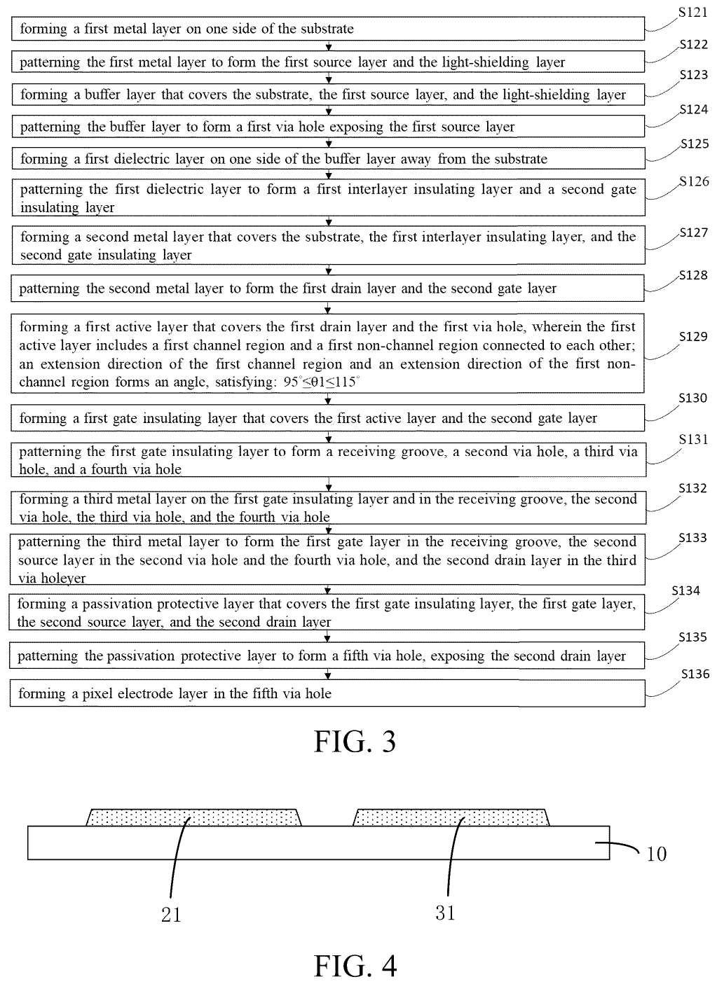

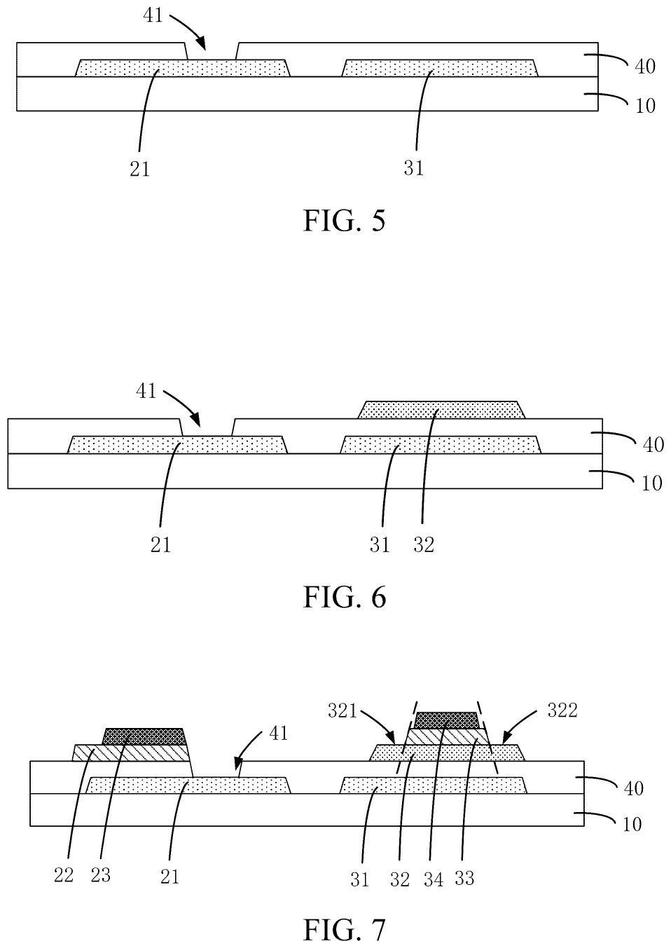

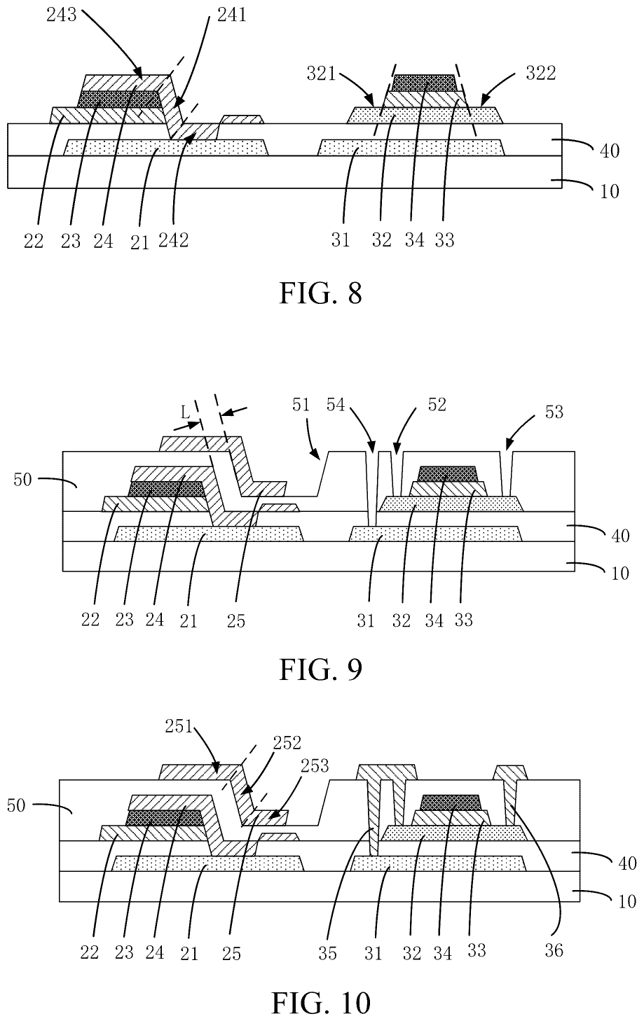

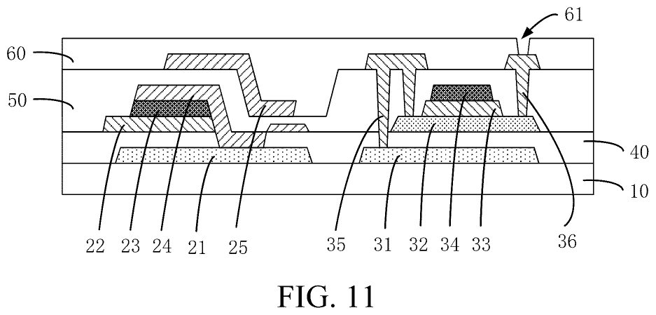

Please refer to FIGS. 1 to 11, which illustrate a display panel provided by this application. The following is a detailed explanation in conjunction with specific embodiments.

The display panel includes a display area AA and a non-display area NA, with the non-display area NA surrounding the display area AA. The display panel further includes a substrate 10, a first thin film transistor (TFT) 20 located in the non-display area NA and including a first drain layer 23 on one side of the substrate 10, and a second TFT 30 located in the display area AA and including a second gate layer 34 on one side of the substrate 10. The first drain layer 23 and the second gate layer 34 are arranged in the same layer.

The substrate 10 could be a glass base plate, but is not limited to this. The second TFT 30 can be a top-gate bottom contact structure.

It should be understood that the “same layer arrangement” refers to being formed through a same photomask process.

By forming the second gate layer 34 and the first drain layer 23 in the same process, this application saves on the photomask process compared to conventional display panels, thereby reducing the number of steps involved.

In some embodiments, the first TFT 20 also includes a first source layer 21 between the first drain layer 23 and the substrate 10; the second TFT 30 includes a light-shielding layer 31 between the second gate layer 34 and the substrate 10. The first source layer 21 and the light-shielding layer 31 are arranged in the same layer.

By forming the light-shielding layer 31 and the first source layer 21 in the same process, this application saves on the photomask process compared to traditional display panels, thereby reducing the number of steps involved.

In some embodiments, the first TFT 20 also includes a first interlayer insulating layer 22 located between the first source layer 21 and the first drain layer 23; the second TFT 30 also includes a second gate insulating layer 33 located between the second gate layer 34 and the light-shielding layer 31. The first interlayer insulating layer 22 and the second gate insulating layer 33 are arranged in the same layer.

By forming the second gate insulating layer 33 and the first interlayer insulating layer 22 in the same process, this application saves on the photomask process compared to conventional display panels, thereby reducing the number of steps involved.

In some embodiments, the first TFT 20 also includes a first gate layer 25 located on one side of the first drain layer 23 away from the substrate 10; the second TFT 30 also includes a second source layer 35 and a second drain layer 36. The second source layer 35 and the second drain layer 36 are arranged in the same layer as the first gate layer 25.

By forming the second source layer 35, the second drain layer 36, and the first gate layer 25 in the same process, this application saves on the photomask process compared to conventional display panels, thereby reducing the number of steps involved.

In some embodiments, the first TFT 20 also includes a first active layer 24. The first active layer 24 covers the first drain layer 23; the first active layer 24 includes a first channel region 241 and a first non-channel region 242 connected to each other; an extension direction of the first channel region 241 has an angle θ1 with the first non-channel region 242, satisfying 95°≤θ1≤115°.

It should be understood that an angle corresponds to the channel of the first TFT 20 is an supplementary angle of the angle θ1. Thus, the first TFT 20 of this application has a vertical channel structure. A specific value of θ1 can be 95°, 100°, 105°, or 115°, or any range composed of any two of these values. It's worth noting that these specific values of 01 are only given as examples, and any value within the range of 95°≤θ1≤115° falls within the protection scope of this application.

This application provides a display panel that, due to the vertical channel structure of the first TFT 20, enhances the carrier mobility of the first TFT 20; additionally, the greater the carrier mobility of the first TFT 20, the shorter a response time of the first TFT 20, giving the first TFT 20 significant advantages as a switch TFT.

In some embodiments, the first active layer 24 also includes a second non-channel region 243; one end of the first channel region 241 is connected to the first non-channel region 242; another end of the first channel region 241 is connected to the second non-channel region 243; the first source layer 21 is connected to the first non-channel region 242; the first drain layer 23 is connected to the second non-channel region 243; the first gate layer 25 includes a first section 251, a second section 252, and a third section 253 connected in sequence. The second section 252 is arranged opposite the first channel region 241. There is a distance L between the second section 252 and the first channel region 241, which satisfies 50 nm≤L≤200 nm.

It should be understood that the first non-channel region 242 is a source region of the first TFT 20; the second non-channel region 243 is a drain region of the first TFT 20.

Specifically, the distance L between the first channel region 241 and the second section 252 can be 50 nm, 80 nm, 100 nm, 150 nm, 180 nm, 200 nm, or any range composed of any two of these values. It's worth noting that these specific values of the distance L are only given as examples, and any value within the range of 50 nm≤L≤200 nm falls within the protection scope of this application.

It should be understood that, due to the vertical channel structure of the first TFT 20, the distance L between the first channel region 241 and the second section 252 is shortened, i.e., a thickness of the first gate insulating layer 50 between the first active layer 24 and the first gate layer 25 is reduced, thereby enhancing the carrier mobility and current of the first TFT 20, and reducing a size of the display panel.

In some embodiments, the display panel also includes a buffer layer 40 and a first gate insulating layer 50; the buffer layer 40 is located on one side of the first source layer 21 and the light-shielding layer 31 away from the substrate 10; the first gate insulating layer 50 is located on one side of the first gate layer 25 away from the substrate 10; the buffer layer 40 and the first gate insulating layer 50 extend from the display area AA of the display panel to the non-display area NA.

In some embodiments, the second thin-film transistor (TFT) 30 also includes a second active layer 32 stacked on the buffer layer 40. The second active layer 32 is disposed corresponding to the light-shielding layer 31. The second active layer 32 includes a third non-channel region 321 and a fourth non-channel region 322; the second source layer 35 is connected to both the light-shielding layer 31 and the third non-channel region 321; the second drain layer 36 is connected to the fourth non-channel region 322.

By using a top-gate self-alignment process for doping or plasma conductivity treatment of the second active layer 32, a third non-channel region 321 and a fourth non-channel region 322 are formed. This process reduces the contact resistance between the second source layer 35, the second drain layer 36, and the second active layer 32. Specifically, this application forms an N-type heavy doping by doping with phosphorus ions.

The second active layer 32 can be made of polysilicon or metal oxide; where polysilicon can be obtained through amorphous silicon laser annealing crystallization or other crystallization methods. The metal oxide can be IGZO, IGTO, IGZO, IGO, IZO, AIZO, or ATZO, which are metal oxides with lower leakage current.

In some embodiments, the display panel also includes a passivation protective layer 60, covering the first gate insulating layer 50, the first gate layer 25, the second source layer 35, and the second drain layer 36.

Specifically, a material of the passivation protective layer 60 can be SiO_{X}, Al₂O₃/SiN_{X}/SiO_{X} laminate, or SiO_{X}/SiN_{X}/SiO_{X} laminate.

By setting the passivation protective layer 60, which covers the first gate insulating layer 50, the first gate layer 25, the second source layer 35, and the second drain layer 36, the passivation protective layer 60 can isolate external moisture, further protecting the performance of the first TFT 20 and the second TFT 30.

In some implementations, the display panel also includes a pixel electrode layer 70 which connects to the second drain layer 36. Specifically, a material of the pixel electrode layer 70 can be ITO, IZO, ITO/Ag/ITO laminate, IZO/Ag/IZO laminate, Mo/Cu laminate, or MoTi/Cu/MoTi laminate.

Accordingly, this application provides a manufacturing method of a display panel, including:

Step S11: providing a substrate 10.

The substrate 10 can be a glass base plate, but not limited to it.

Step S12: forming a first TFT 20 and a second TFT 30 on one side of the substrate 10, wherein the first TFT 20 is located in the non-display area NA, and the second TFT 30 is located in the display area AA; the first TFT 20 includes a first drain layer 23 on one side of the substrate 10; the second TFT 30 includes a second gate layer 34 on one side of the substrate 10; and the first drain layer 23 and the second gate layer 34 are arranged in the same layer.

This application enables the formation of the second gate layer 34 and the first drain layer 23 in the same process. Compared to conventional display panels, this can save on photomask processes and consequently reduce the number of manufacturing steps.

In some embodiments, forming the first thin-film transistor (TFT) 20 and the second TFT 30 on one side of the substrate 10 includes:

Step S121: forming a first metal layer 101 on one side of the substrate 10.

Specifically, the first metal layer 101 can be made of a material such as Mo, Mo/Al laminate, Mo/Cu laminate, MoTi/Cu laminate, MoTi/Cu/MoTi laminate, Ti/Al/Ti laminate, Ti/Cu/Ti laminate, Mo/Cu/IZO laminate, IZO/Cu/IZO laminate, or Mo/Cu/ITO laminate.

Step S122: patterning the first metal layer 101 to form the first source layer 21 and the light-shielding layer 31.

By forming the light-shielding layer 31 and the first source layer 21 in the same process, the present application saves on photomask processes compared to conventional display panels, thus reducing the number of steps.

In some embodiments, after patterning the first metal layer 101 to form the first source layer 21 and the light-shielding layer 31, the manufacturing method further includes:
Step S123: forming a buffer layer 40 that covers the substrate 10, the first source layer 21, and the light-shielding layer 31.

Specifically, a material of the buffer layer 40 can be SiO_{X} or a SiN_{X}/SiO_{X} laminate.

Step S124: patterning the buffer layer 40 to form a first via hole 41 exposing the first source layer 21.

Step S125: forming a first dielectric layer 102 on one side of the buffer layer 40 away from the substrate 10.

Step S126: patterning the first dielectric layer 102 to form a first interlayer insulating layer 22 and a second gate insulating layer 33.

The first dielectric layer 102 can be made of SiO_{X}, Al₂O₃/SiN_{X}/SiO_{X} laminate, or SiO_{X}/SiN_{X}/SiO_{X} laminate.

In some embodiments, after patterning the buffer layer 40 to form the first via hole 41 exposing the first source layer 21, the manufacturing method further includes:

Step S1241: forming a second active layer 32 on a surface of the buffer layer 40 corresponding to the light-shielding layer 31.

In some embodiments, after patterning the first dielectric layer 102 to form the first interlayer insulating layer 22 and the second gate insulating layer 33, the manufacturing method further includes:

Step S127: forming a second metal layer 103 that covers the substrate 10, the first interlayer insulating layer 22, and the second gate insulating layer 33.

Specifically, the second metal layer 103 can be made of a material like Mo, Mo/Al laminate, Mo/Cu laminate, MoTi/Cu laminate, MoTi/Cu/MoTi laminate, Ti/Al/Ti laminate, Ti/Cu/Ti laminate, Mo/Cu/IZO laminate, IZO/Cu/IZO laminate, or Mo/Cu/ITO laminate.

Step S128: patterning the second metal layer 103 to form the first drain layer 23 and the second gate layer 34.

By forming the second gate layer 34 and the first drain layer in the same process, this application saves on photomask processes compared to conventional display panels, thus reducing the number of manufacturing steps.

In some embodiments, after patterning the second metal layer 103 to form the first drain layer 23 and the second gate layer 34, the manufacturing method further includes:

Step S1281: performing a conductivity treatment on the second active layer 32 to form a third non-channel region 321 and a fourth non-channel region 322.

This application uses a top-gate self-alignment process for doping or plasma conductivity treatment to form the third non-channel region 321 and the fourth non-channel region 322.

In some embodiments, after patterning the second metal layer 103 to form the first drain layer 23 and the second gate layer 34, the manufacturing method further includes:

Step S129: forming a first active layer 24 that covers the first drain layer 23 and the first via hole 41. The first active layer 24 includes a first channel region 241 and a first non-channel region 242 connected to each other, where an extension direction of the first channel region 241 and an extension direction of the first non-channel region 242 forms an angle θ1, satisfying: 95°≤θ1≤115°.

Specifically, the first active layer 24 can be a high mobility and stability crystalline or amorphous oxide semiconductor or other types of semiconductors; a material of the first active layer 24 can be IGZO, IGTO, IGZO, IGO, IZO, AIZO, or ATZO.

It is understood that an angle corresponds to the channel of the first TFT 20 is a complementary angle of the angle θ1, indicating that the first TFT 20 has a vertical channel structure. Specific θ1 values can be 95°, 100°, 105°, 115°, or any range composed of two of these values, and any value within the range of 95°≤θ1≤115° is within the protection scope of this application.

The display panel provided in this application, due to the vertical channel structure of the first thin-film transistor (TFT) 20, enhances the carrier mobility of the first TFT 20. Moreover, the higher the carrier mobility of the first TFT 20, the shorter its response time, giving the first TFT 20 a significant advantage as a switching TFT.

In some embodiments, after forming the first active layer 24 that covers the first drain layer 23 and the first via hole 41, the manufacturing method further includes:

Step S130: forming a first gate insulating layer 50 that covers the first active layer 24 and the second gate layer 34.

It is understood that the first gate insulating layer 50 extends from the non-display area NA to the display area AA; in other words, the first gate insulating layer 50 also covers the second active layer 32, the second gate insulating layer 33, and the second gate layer 34 of the second TFT 30.

Step S131: patterning the first gate insulating layer 50 to form a receiving groove 51, a second via hole 52, a third via hole 53, and a fourth via hole 54.

Step S132: forming a third metal layer 104 on the first gate insulating layer 50 and in the receiving groove 51, the second via hole 52, the third via hole 53, and the fourth via hole 54.

In detail, a material of the third metal layer 104 can be Mo, Mo/Al laminate, Mo/Cu laminate, MoTi/Cu laminate, MoTi/Cu/MoTi laminate, Ti/Al/Ti laminate, Ti/Cu/Ti laminate, Mo/Cu/IZO laminate, IZO/Cu/IZO laminate, or Mo/Cu/ITO laminate.

Step S133: patterning the third metal layer 104 to form the first gate layer 25 in the receiving groove 51, the second source layer 35 in the second via hole 52 and the fourth via hole 54, and the second drain layer 36 in the third via hole 53.

Compared to conventional display panels, this application saves on photomask processes by forming the second source layer 35, the second drain layer 36, and the first gate layer 25 in the same process, thus reducing the number of manufacturing steps.

In some embodiments, after patterning the third metal layer 104 to form the first gate layer 25 in the receiving groove 51, the second source layer 35 in the second via hole 52 and the fourth via hole 54, and the second drain layer 36 in the third via hole 53, the manufacturing method further includes:

Step S134: forming a passivation protective layer 60 that covers the first gate insulating layer 50, the first gate layer 25, the second source layer 35, and the second drain layer 36.

In detail, a material of the passivation protective layer 60 can be SiO_{X}, Al₂O₃/SiN_{X}/SiO_{X} laminate, or SiO_{X}/SiN_{X}/SiO_{X} laminate.

By setting the passivation protective layer 60, this application ensures that the passivation protective layer 60 covers the first gate insulating layer 50, the first gate layer 25, the second source layer 35, and the second drain layer 36. The passivation protective layer 60 can isolate external moisture, further protecting the performance of the first TFT 20 and the second TFT 30.

Step S135: patterning the passivation protective layer 60 to form a fifth via hole 61, exposing the second drain layer 36.

Step S136: forming a pixel electrode layer 70 in the fifth via hole 61.

Specifically, a material of the pixel electrode layer 70 can be ITO, IZO, ITO/Ag/ITO laminate, IZO/Ag/IZO laminate, Mo/Cu laminate, or MoTi/Cu/MoTi laminate.

Correspondingly, this application also provides a display device that includes the aforementioned display panel or a display panel manufactured using the manufacturing method described above.

Specifically, the display device can be mobile electronic devices such as phones and tablets; the display device can also be computing devices, televisions, in-vehicle computers, or other devices equipped with display functions.

This display device, through the formation of the light-shielding layer 31 and the first source layer 21 in the same process, and the formation of the second gate insulating layer 33 and the first interlayer insulating layer 22 in the same process, and the formation of the second gate layer 34 and the first drain layer 23 in the same process, and the formation of the second source layer 35, the second drain layer 36, and the first gate layer 25 in the same process, saves on photomask processes compared to conventional display panels, thereby reducing the number of manufacturing steps. Additionally, due to the vertical channel structure of the first TFT 20 located in the non-display area NA, the carrier mobility of the first TFT 20 is enhanced, which in turn reduces a size of the display panel, enabling a narrow bezel/border design for the display device.

In summary, although the detailed description of the embodiments of this application is provided as above, the described embodiments are not intended to limit this application. Those skilled in the art should understand that they can still modify the technical solutions recorded in the aforementioned embodiments or equivalently replace some of the technical features; and these modifications or replacements do not deviate from the essence of the technical solutions of the embodiments of this application and still fall within the protection scope of the present application.

What is claimed is:

1. A display panel, comprising:
a display area and a non-display area, the non-display area surrounding the display area;
a substrate;
a first thin film transistor (TFT) disposed in the non-display area and comprising a first drain layer, the first drain layer disposed on one side of the substrate; and
a second thin film transistor (TFT) disposed in the display area and comprising a second gate layer, the second gate layer disposed on one side of the substrate;
wherein the first drain layer and the second gate layer are arranged in a same layer.

2. The display panel according to claim 1, wherein the first TFT further comprises a first source layer, the first source layer is disposed between the first drain layer and the substrate;
the second TFT further comprises a light-shielding layer, the light-shielding layer is disposed between the second gate layer and the substrate; and
the first source layer and the light-shielding layer are arranged in a same layer.

3. The display panel according to claim 2, wherein the first TFT further comprises a first interlayer insulating layer, the first interlayer insulating layer is disposed between the first source layer and the first drain layer;
the second TFT further comprises a second gate insulating layer, the second gate insulating layer is disposed between the second gate layer and the light-shielding layer; and
the first interlayer insulating layer and the second gate insulating layer are arranged in a same layer.

4. The display panel according to claim 1, wherein the first TFT further comprises a first gate layer,
the first gate layer is disposed on one side of the first drain layer away from the substrate;
the second TFT further comprises a second source layer and a second drain layer; and
the second source layer and the second drain layer are arranged in a same layer as the first gate layer.

5. The display panel according to claim 4, wherein the first TFT further comprises a first active layer, and the first active layer covers the first drain layer;
the first active layer comprises a first channel region and a first non-channel region connected to each other; and
an extension direction of the first channel region and an extension direction of the first non-channel region forms an angle θ1, which satisfies: 95°≤θ1≤115°.

6. The display panel according to claim 5, wherein the first active layer further comprises a second non-channel region, one end of the first channel region is connected to the first non-channel region, and another end of the first channel region is connected to the second non-channel region;
the first gate layer comprises a first section, a second section, and a third section connected in sequence;
the second section is arranged corresponding to the first channel region, and a distance L is present between the first channel region and the second section, which satisfies: 50 nm≤L≤200 nm.

7. A manufacturing method of a display panel, comprising following steps:
providing a substrate; and
forming a first thin film transistor (TFT) and a second thin film transistor (TFT) on one side of the substrate, wherein the first TFT is disposed in the non-display area, and the second TFT is disposed in the display area;
wherein the first TFT comprises a first drain layer, and the first drain layer is disposed on one side of the substrate;
the second TFT comprises a second gate layer, the second gate layer is disposed on one side of the substrate;
the first drain layer and the second gate layer are arranged in a same layer.

8. The manufacturing method of the display panel according to claim 7, wherein the step of
forming the first TFT and the second TFT on one side of the substrate comprises:
forming a first metal layer on one side of the substrate;
patterning the first metal layer to form a first source layer and a light-shielding layer.

9. The manufacturing method of the display panel according to claim 8, wherein after patterning the first metal layer to form the first source layer and the light-shielding layer, the manufacturing method further comprises:
forming a buffer layer covering the substrate, the first source layer, and the light-shielding layer;
patterning the buffer layer to form a first via hole exposing the first source layer;
forming a first dielectric layer on one side of the buffer layer away from the substrate; and
patterning the first dielectric layer to form a first interlayer insulating layer and a second gate insulating layer.

10. The manufacturing method of the display panel according to claim 9, wherein after patterning the first dielectric layer to form the first interlayer insulating layer and the second gate insulating layer, the manufacturing method further comprises:
forming a second metal layer covering the substrate, the first interlayer insulating layer, and the second gate insulating layer; and
patterning the second metal layer to form a first drain layer and a second gate layer.

11. The manufacturing method of the display panel according to claim 10, wherein after patterning the second metal layer to form the first drain layer and the second gate layer, the manufacturing method further comprises:
forming a first active layer covering the first drain layer and the first via hole, wherein the first active layer comprises a first channel region and a first non-channel region connected to each other; and an extension direction of the first channel region and an extension direction of the first non-channel region forms an angle θ1, which satisfies: 95°≤θ1≤115°.

12. The manufacturing method of the display panel according to claim 10, wherein after forming the first active layer covering the first drain layer and the first via hole, the manufacturing method further comprises:
forming a first gate insulating layer covering the first active layer and the second gate layer; patterning the first gate insulating layer to form a receiving groove, a second via hole, a third via hole, and a fourth via hole;
forming a third metal layer on the first gate insulating layer and in the receiving groove, the second via hole, the third via hole, and the fourth via hole; and
patterning the third metal layer to form a first gate layer in the receiving groove, forming a second source layer in the second via hole and the fourth via hole, and forming a second drain layer in the third via hole.

13. A display device, comprising a display panel, wherein the display panel comprises:
a display area and a non-display area, the non-display area surrounding the display area;
a substrate;
a first thin film transistor (TFT) disposed in the non-display area and comprising a first drain layer, the first drain layer disposed on one side of the substrate; and
a second thin film transistor (TFT) disposed in the display area and comprising a second gate layer, the second gate layer disposed on one side of the substrate;
wherein the first drain layer and the second gate layer are arranged in a same layer.

14. The display device according to claim 13, wherein the first TFT further comprises a first source layer, the first source layer is disposed between the first drain layer and the substrate;
the second TFT further comprises a light-shielding layer, the light-shielding layer is disposed between the second gate layer and the substrate; and
the first source layer and the light-shielding layer are arranged in a same layer.

15. The display device according to claim 14, wherein the first TFT further comprises a first interlayer insulating layer, the first interlayer insulating layer is disposed between the first source layer and the first drain layer;
the second TFT further comprises a second gate insulating layer, the second gate insulating layer is disposed between the second gate layer and the light-shielding layer; and
the first interlayer insulating layer and the second gate insulating layer are arranged in a same layer.

16. The display device according to claim 13, wherein the first TFT further comprises a first gate layer, the first gate layer is disposed on one side of the first drain layer away from the substrate;
the second TFT further comprises a second source layer and a second drain layer; and
the second source layer and the second drain layer are arranged in a same layer as the first gate layer.

17. The display device according to claim 16, wherein the first TFT further comprises a first active layer, and the first active layer covers the first drain layer;
the first active layer comprises a first channel region and a first non-channel region connected to each other; and
an extension direction of the first channel region and an extension direction of the first non-channel region forms an angle θ1, which satisfies: 95°≤θ1≤115°.

18. The display device according to claim 17, wherein the first active layer further comprises a second non-channel region, one end of the first channel region is connected to the first non-channel region, and another end of the first channel region is connected to the second non-channel region; the first gate layer comprises a first section, a second section, and a third section connected in sequence;
the second section is arranged corresponding to the first channel region, and a distance L is present between the first channel region and the second section, which satisfies: 50 nm≤L≤200 nm.
